(19) United States
(12) Patent Application Publication
(10) Pub. No.: US 2026/0047509 A1
(43) Pub. Date: Feb. 12, 2026

(54) Electronic Device Having Pins with a Bent Profile

(71) Applicant: Infineon Technologies AG, Neubiberg (DE)

(72) Inventors: Javier Acuna, Soest (DE); Marco Ludwig, Wickede/Ruhr (DE); Regina Nottelmann, Lippetal (DE)

(21) Appl. No.: 18/798,953

(22) Filed: Aug. 9, 2024

(51) Int. Cl. H01L 23/498; H01L 23/057; H01L 23/31; H01L 23/538; H01L 25/00; H01L 25/065; H01L 29/16; H01R 12/58

(52) U.S. Cl. CPC H01L 23/49811; H01L 23/057; H01L 23/5383; H01L 25/0655; H01L 25/50; H01L 23/3107; H01R 12/585; H10D 62/8325

(57) ABSTRACT

An electronic device includes one or more power semiconductor dies and a plurality of sleeves attached to a substrate. The electronic device further includes an electrically insulative enclosure that laterally encloses the one or more power semiconductor dies, and a plurality of pins providing an electrical interface for the electronic device. A proximal end of each pin is inserted into one of the plurality of sleeves. One or more of the pins has a bent profile and includes a first segment and a third segment that are oriented substantially perpendicular to the substrate and are offset from one another in a direction that is parallel to the substrate, and a second segment interposed between and electrically coupling the first segment and the third segment. At least a part of the first segment and at least a part of the second segment are covered by an electrically insulative material.

### BACKGROUND

Demand for electronic devices for power applications continues to increase rapidly across a wide range of industries, including automotive, consumer electronics, renewable energy, manufacturing, and medical, among many others. Developments in semiconductor materials such as silicon carbide (SiC) and gallium nitride (GaN) have enabled power electronic devices with advantageous features such as smaller footprint, higher voltage and current capabilities, and faster switching speeds.

Reducing the size of power electronic devices and their respective components may reduce manufacturing cost and improve the ability to meet demand for these devices. SiC chips in particular generally have a smaller footprint and may enable smaller substrates and enclosures to be used in manufacturing power electronic devices, providing a potential cost savings coupled with performance advantages of SiC. However, reducing the size of power electronic devices may be constrained by creepage and clearance requirements, particularly for high voltage applications. Additionally, some applications require a compatible power electronic device having a specific external interface layout.

Thus, there is a need for a solution that enables smaller power electronic devices that are cheaper to manufacture but meet creepage and clearance requirements and are compatible with existing applications.

### SUMMARY

According to an embodiment of an electronic device, the electronic device comprises: a substrate; one or more power semiconductor dies attached to the substrate; an electrically insulative enclosure that laterally encloses the one or more power semiconductor dies; a plurality of sleeves attached to the substrate; and a plurality of pins providing an electrical interface for the electronic device, each pin having a proximal end inserted into one of the plurality of sleeves and a distal end, wherein one or more of the pins has a bent profile and comprises: a first segment and a third segment that are oriented substantially perpendicular to the substrate and are offset from one another by a distance in a direction that is parallel to the substrate, the first segment comprising the proximal end of the pin and the third segment comprising the distal end of the pin; and a second segment interposed between and electrically coupling the first segment and the third segment, wherein at least a part of the first segment and at least a part of the second segment are covered by an electrically insulative material.

According to an embodiment of method for producing an electronic device, the method comprises: attaching one or more power semiconductor dies and a plurality of sleeves to a substrate; providing a plurality of pins, wherein one or more of the pins has a bent profile and comprises a first segment and a third segment that are oriented substantially perpendicular to the substrate and are offset from one another by a distance in a direction that is parallel to the substrate, the first segment comprising the proximal end of the pin and the third segment comprising the distal end of the pin; and a second segment interposed between and electrically coupling the first segment and the third segment; for each of the plurality of pins, inserting a proximal end of the pin into one of the plurality of sleeves; providing the one or more of the pins having a bent profile with at least a part of the first segment and at least a part of the second segment covered by an electrically insulative material, or, before or after inserting the proximal end of each of the one or more of the pins having a bent profile into one of the plurality of sleeves, applying an electrically insulative material to at least a part of the first segment and at least a part of the second segment of each of the one or more of the pins having a bent profile; and enclosing the one or more power semiconductor dies in an electrically insulative enclosure such that a distal end of each of the plurality of pins is outside the enclosure and provides an electrical interface for the electronic device.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a perspective view of an electronic device, according to an embodiment.

FIG. 2 illustrates a partial side cross-sectional view of an electronic device, according to an embodiment.

FIGS. 3A-3D illustrate partial side cross-sectional views of an electronic device, according to embodiments.

FIGS. 4A-4C illustrate partial side cross-sectional views of an electronic device, according to embodiments.

FIGS. 5A-5C illustrates top plan views of an electronic device, according to embodiments.

FIGS. 6A-6G illustrate partial side cross-sectional views of a method for producing an electronic device, according to embodiments.

### DETAILED DESCRIPTION

Described herein is an electronic device having one or more power semiconductor dies attached to a substrate and a plurality of pins that provide an electrical interface for the electronic device. An electrically insulative enclosure laterally encloses the one or more power semiconductor dies in an interior space that is delimited by the substrate and the enclosure. Each pin has a proximal end that is inserted into a sleeve attached to the substrate and a distal end that is outside the enclosure. Each sleeve may be electrically coupled to one or more of the power semiconductor dies by traces on the substrate, bond wires, ribbons, metallic clips, or other means.

At least one of the pins that provides an electrical interface for the electronic device has a bent profile in which the distal end of the pin is offset from the proximal end in a direction that is parallel to the substrate. A bent pin may be oriented relative to an adjacent pin (either a straight pin or another bent pin) such that the distal end of the bent pin is offset away from the adjacent pin and the effective spacing between the bent pin and the adjacent pin is increased. This greater effective spacing may improve creepage and/or clearance distance between the adjacent pins, potentially enabling a smaller, cheaper substrate to be used by placing the pins closer to each other without exceeding creepage and/or clearance requirements. Additionally, the greater effective spacing between a bent pin and an adjacent pin may provide more flexibility in arranging pins on the substrate, as high voltage pins may be able to be placed adjacent to low voltage pins without exceeding the creepage and/or clearance requirements. Utilizing bent pins in manufacturing the electronic device may also enable a standard external pin layout to be provided with a smaller substrate, potentially reducing the manufacturing cost of the electronic device while maintaining compatibility with existing applications.

Described next, with reference to the figures, are exemplary embodiments of an electronic device having pins with a bent profile.

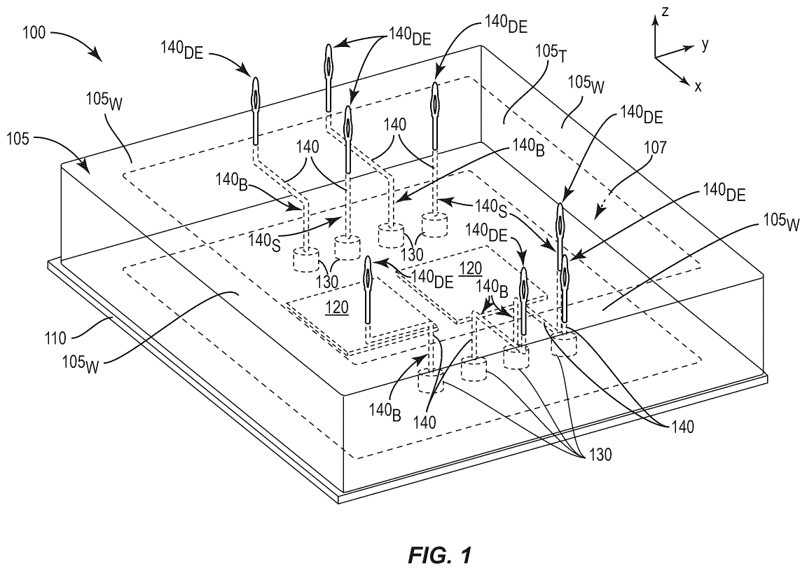

FIG. 1 illustrates a perspective view of an electronic device 100, according to an embodiment. The electronic device 100 may be a power semiconductor module, component, or other packaged assembly. The electronic device 100 includes one or more power semiconductor dies 120 attached to a substrate 110. An electrically insulative enclosure 105 laterally encloses (e.g., in the x and y directions) the one or more power semiconductor dies 120 in an interior space 107 that is delimited by the substrate 110 and the enclosure 105 (e.g., walls 105_{W} and a top 105_{T} of the enclosure 105). For reference hereafter, the substrate 110 is parallel to the x and y directions.

The power semiconductor die(s) 120 may each include one or more devices, including transistors, diodes, resistors, capacitors, and/or other types of active or passive devices. One or more of the power semiconductor dies 120 may be a vertical power semiconductor die (e.g., a vertical power transistor die). For a vertical power transistor die, the primary current flow path is between the front and back sides of the power semiconductor die 120 (along the z direction in FIG. 1). In one embodiment, the one or more power semiconductor dies 120 are SiC transistor dies such as SiC power MOSFET (metal-oxide-semiconductor field-effect transistor) dies. One or more of the power semiconductor dies 120 may be a Si power MOSFET die, HEMT (high-electron mobility transistor) die, IGBT (insulated-gate bipolar transistor) die, JFET (junction filed-effect transistor) die, etc. The power semiconductor dies 120 attached to the substrate 110 may all be of a similar or identical design (e.g., device type, structure, materials, dimensions, etc.), or some or each of the power semiconductor dies 120 may have different designs. Various arrangements of designs of power semiconductor dies 120 on the substrate 110 are contemplated. The power semiconductor die(s) 120 and/or their constituent devices may be arranged to form all or part of a power electronics circuit such as a DC/AC inverter, a DC/DC converter, an AC/DC converter, an AC/AC converter, a multi-phase inverter, an H-bridge, motor driver, etc. In some examples, a power electronics circuit that includes the power semiconductor die(s) 120 is a half-bridge or full-bridge circuit.

Examples of the substrate 110 include a DCB (direct copper bonded) or AMB (active metal brazed) substrate, printed circuit board (PCB), lead frame, or other substrate, e.g., insulated metal substrate (IMS), etc. The substrate 110 may include one or more insulating layers (e.g., ceramic, polyimide, etc.) and metallization layers such as contact pads and/or traces that are electrically coupled to the power semiconductor die(s) 120.

The enclosure 105 of FIG. 1 may be a frame enclosure. A frame enclosure may include one or more pieces of metal, plastic, composite, and/or other suitable material that is structured and arranged to enclose the power semiconductor die(s) 120. The walls 105_{W} and the top 105_{T} of the enclosure may be part of a single piece or may be separate pieces. For example, the top 105_{T} may be a lid. In some examples, the enclosure 105 is a molded enclosure that is attached to the substrate 110. That is, the walls 105_{W} and/or the top 105_{T} may be formed from a mold compound. A mold compound is a plastic encapsulant typically formed from an organic resin such as an epoxy resin. The plastic encapsulant may include fillers such as non-melting inorganic materials. Catalysts may be used to accelerate the cure reaction of the organic resin. Other materials such as flame retardants, adhesion promoters, ion traps, stress relievers, colorants, etc. may be added to the plastic encapsulant, as appropriate. The mold compound may be formed by injection molding, compression molding, film-assisted molding (FAM), reaction injection molding (RIM), resin transfer molding (RTM), blow molding, etc.

The electronic device 100 includes a plurality of sleeves 130 attached to the substrate 110. The sleeves 130 may be formed of a metal or metal alloy such as copper, aluminum, etc., and may further include an electrically insulative cover or coating. One or more sleeves 130 may be attached and electrically coupled to a metallization layer of the substrate 110 (e.g., a pad, a trace). Each of a plurality of pins 140 is inserted into one of the plurality of sleeves 130. Each of the plurality of pins 140 protrudes through the enclosure 105 such that a distal end 140_{DE} of each of the pins 140 is outside of the enclosure 105. The pins 140 thus provide an electrical interface for the electronic device 100. The pins 140 may be formed of copper, aluminum, an alloy (e.g., a nickel tin alloy), or another electrically conductive material.

According to an embodiment, one or more of the pins 140 has a bent profile. Hereafter, pins 140 that have a bent profile may be referred to as bent pins 140_{B}. Pins 140 having a straight profile may be referred to as straight pins 140_{S}. The electronic device 100 of FIG. 1 illustrates examples of both bent pins 140_{B} and straight pins 140_{S}.

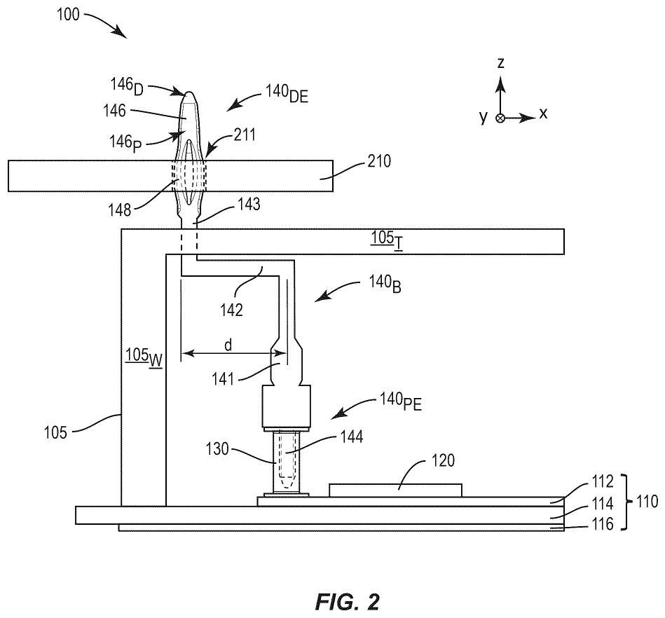

FIG. 2 illustrates a partial side cross-sectional view of the electronic device 100, according to an embodiment. The substrate 110 includes an insulating layer 114 and metallization layers 112 and 116. The insulating layer 114 may include a ceramic, a polymer such as polyimide, etc. The metallization layers 112 and 116 may each include copper, aluminum, an alloy, etc. The power semiconductor die 120 illustrated in FIG. 2 is attached to the metallization layer 112. The metallization layer 112 may include one or more traces and/or contact pads. The sleeve 130 of FIG. 2 is also attached to the metallization layer 112 and may be electrically coupled to the power semiconductor die 120 through the metallization layer 112 (e.g., for a power semiconductor die 120 that includes a vertical power transistor). In other examples, the semiconductor die 120 and the sleeve 130 may be attached to different islands of the metallization layer 112 (e.g., pads or traces) and may be electrically coupled to one another by other means such as a bond wire(s), ribbon(s), a metallic clip, etc. The metallization layer 116 may be configured to attach the electronic device 100 to a module or other assembly such as a heat sink (e.g., by soldering). Other arrangements of the metallization layers 112 and/or 116, the insulating layer 114, and other metallization and/or insulating layers of the substrate 110 are contemplated.

The bent pin 140_{B} includes a first segment 141, a second segment 142, and a third segment 143. The first segment 141 and the third segment 143 are oriented substantially perpendicular to the substrate 110 and are offset from one another by a distance d in the x direction (i.e., parallel to the substrate 110) in FIG. 2.

The first segment 141 includes a proximal end 140_{PE} of the pin 140_{B} that is inserted into the sleeve 130. In this example, the proximal end 140_{PE} of the pin 140_{B} is a press-fit end having an anchoring part 144 that is inserted into the sleeve 130. Examples in which the proximal end 140_{PE} is soldered to the sleeve 130 or directly to the substrate 110 are contemplated.

The third segment 143 includes the distal end 140_{DE} of the pin 140_{B} that is outside of the enclosure 105. In this example, the third segment 143 protrudes through the top 105_{T} of the enclosure 105.

The second segment 142 is interposed between and electrically couples the first segment 141 and the third segment 143. In this example, the second segment 142 extends between the first segment 141 and the third segment 143 in the x direction such that the second segment 142 is substantially parallel to the substrate 110. That is, in the example of FIG. 2, the second segment 142 is oriented at about 90 degrees relative to the first segment 141 and the third segment 143. This is only an example, and the second segment 142 is not required to be substantially parallel to the substrate 110 and may be oriented at other angles relative to the first segment 141 and the third segment 143.

In this example, the distal end 140_{DE} of the bent pin 140_{B} of FIG. 2 is a press-fit end that includes a tip part 146 and a deformable part 148 adjoining the tip part 146. The tip part 146 has a proximal region 146_{P} adjoining the deformable part 148 and a distal region 146_{D} that is narrower (e.g., in the x direction) than the proximal region 146_{P}. The tip part 146 is configured to guide the press-fit end, e.g., into an opening 211 of a printed circuit board 210. The deformable part 148 is configured to deform upon insertion into the opening 211 of the printed circuit board 210. Note that the printed circuit board 210 is included here for illustrative purposes and is not a requirement of the electronic device 100. In other examples, the distal end 140_{DE} of the bent pin 140_{B} may be configured to be soldered to the printed circuit board 210.

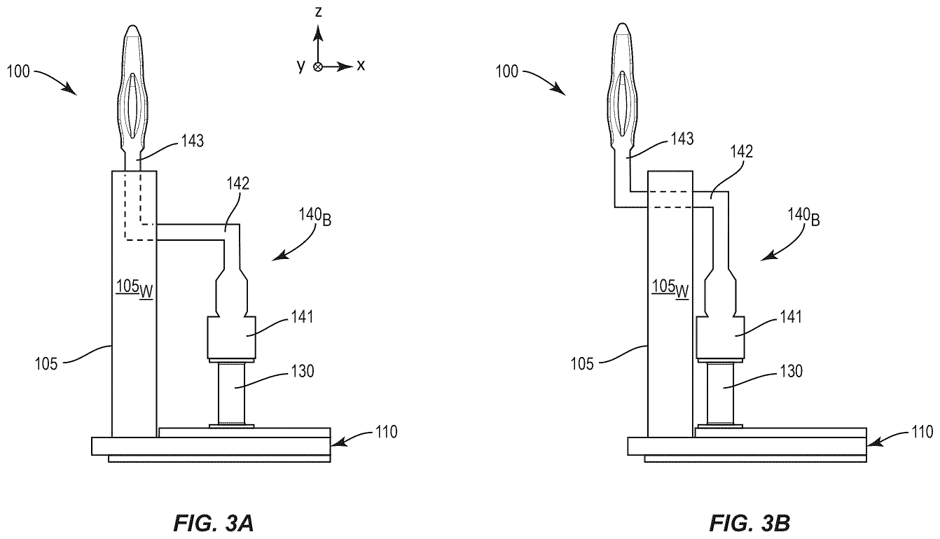

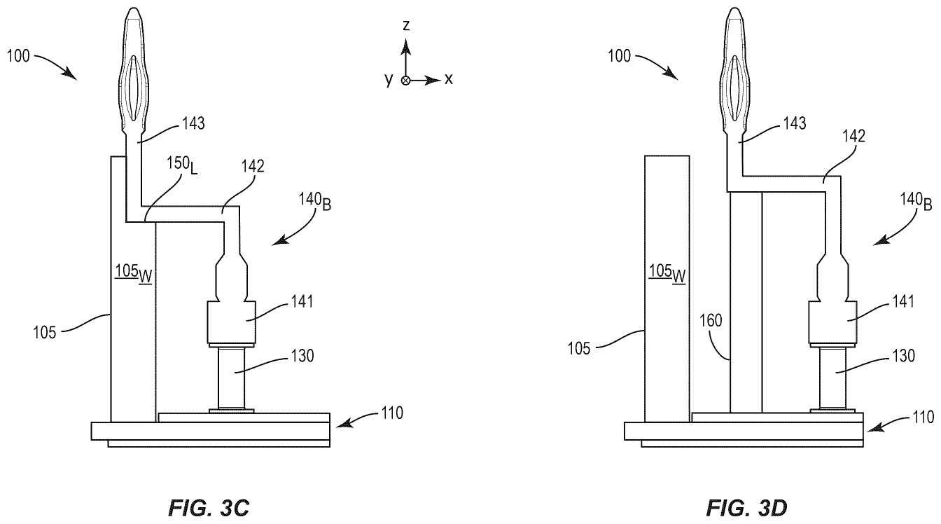

FIGS. 3A-3D illustrate partial side cross-sectional views of the electronic device 100, according to embodiments. FIGS. 3A-3D specifically illustrate examples of structurally supporting the bent pin 140_{B}, e.g., against torque and bending when inserting the proximal end 140_{PE} into a sleeve and/or when inserting the distal end 140_{DE} into a printed circuit board (e.g., the printed circuit board 210 of FIG. 2) or other device.

FIGS. 3A and 3B illustrate examples in which the enclosure 105 is a molded frame 105 and the bent pin 140_{B} is partly embedded in the molded frame 105. In FIG. 3A, parts of the second segment 142 and the third segment 143 are embedded in the molded frame 105, and the third segment 143 protrudes from the wall 105_{W} of the molded frame 105 in the z direction. In FIG. 3B, the second segment 142 extends through the wall 105_{W} of the molded frame 105 in the x direction. In these examples, the first segment 141 is not embedded in the molded frame 105, although examples in which at least part of the first segment 141 is embedded in the molded frame 105 are contemplated. The bent pin 140_{B} may be partly embedded in the molded frame 105 during formation of the molded frame 105, e.g., by inserting the bent pin 140_{B} into a mold and injecting a liquified mold compound around a portion of the bent pin 140_{B}.

In the example of FIG. 3C, parts of the second segment 142 and third segment 143 of the bent pin 140_{B} are supported by a ledge 105_{L} in the wall 105_{W} of the enclosure 105.

In the example of FIG. 3D, the bent pin 140_{B} is supported by a support 160 that is separate from the enclosure 105 and is interposed between the substrate 110 and the second segment 142 and the third segment 143 of the pin 140_{B}. In other examples, the support 160 may by interposed between only the second segment 142 and the substrate 110 or between only the third segment 143 and the substrate 110. The support 160 may be a block, pillar, or other structure of material (e.g., an electrically insulative material) that is attached to the substrate 110.

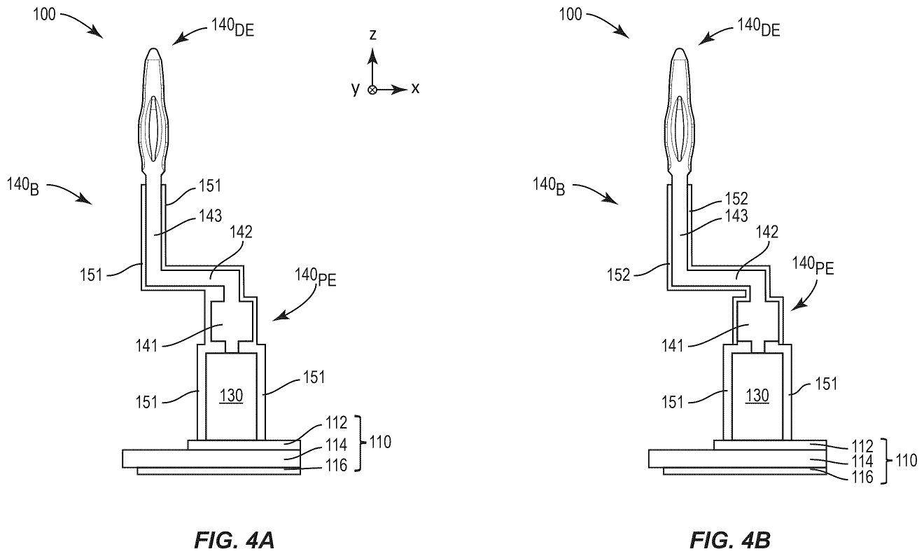

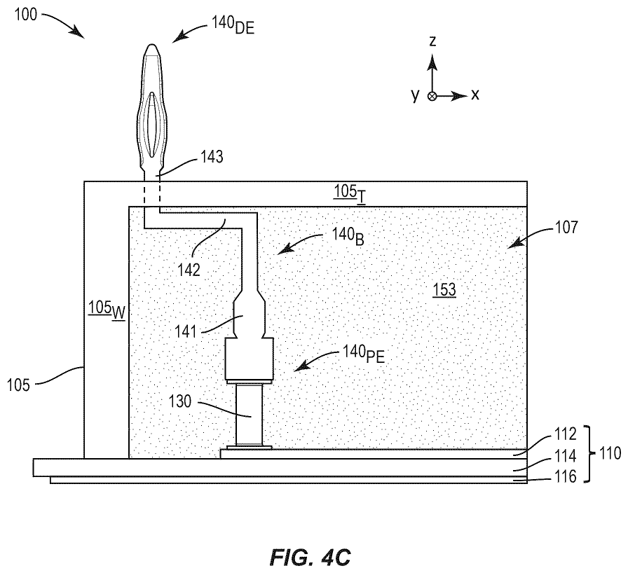

FIGS. 4A-4C illustrate partial side cross-sectional views of the electronic device 100, according to embodiments. FIGS. 4A-4C specifically illustrate examples in which part of the bent pin 140_{B} is covered by an electrically insulative material that provides an isolation layer for the bent pin 140_{B}. One or more of the bent pins 140_{B} of any of the examples described herein may be covered by an electrically insulative material as illustrated in FIGS. 4A-4C.

In the example of FIG. 4A, at least part of the first segment 141, the second segment 142, the third segment 143, and the sleeve 130 are covered by a first electrically insulative layer 151. The first electrically insulative layer 151 may be applied, e.g., by a jetting, spraying or other type of deposition or lamination process, after the bent pin 140_{B} is inserted into the sleeve 130. In some examples, the first electrically insulative layer 151 may be an enamelled coating or other coating, tape, or film (e.g., a polyimide coating, tape, or film). Other examples are contemplated, including examples in which parts of the first segment 141, the second segment 142, and/or the third segment 143 are uncovered or covered by different materials (e.g., the first electrically insulative layer 151 that covers the first segment 141 includes a first material and the first electrically insulative layer 151 that covers the second segment 142 and/or the third segment 143 includes a second, different material).

FIG. 4B illustrates an example in which the first electrically insulative layer 151 covers the sleeve 130 and a second electrically insulative layer 152 covers the bent pin 140_{B}. The first electrically insulative layer 151 and the second electrically insulative layer 152 may, for example, be applied to the sleeve 130 and the bent pin 140_{B}, respectively, after inserting the bent pin 140_{B} into the sleeve 130 so as to create a cemented joint between the sleeve 130 and the bent pin 140_{B}. In some examples, the bent pin 140_{B} may be provided with the electrically insulative layer 152 having been previously applied. The second electrically insulative layer 152 may be a coating, tape, film, sleeve, or other structure. The second electrically insulative layer 152 may include a polymer such as polyimide. In this example, the second electrically insulative layer 152 covers at least part of the first segment 141, the second segment 142, and the third segment 143. Examples in which parts of the first segment 141, the second segment 142, and/or the third segment 143 are not covered by the second electrically insulative layer 152 and/or are covered by a different material (e.g., the first electrically insulative layer 151) are contemplated.

In the examples of FIGS. 4A and 4B, the distal end 140_{DE} of the bent pin 140_{B} is uncovered, e.g., to enable the distal end 140_{DE} to be attached and electrically coupled to a printed circuit board (e.g., the printed circuit board 210 of FIG. 2).

FIG. 4C illustrates an example in which the electrically insulative material that covers part of the bent pin 140_{B} is a potting compound 153 that at least partially fills the interior space 107 delimited by the enclosure 105 and the substrate 110.

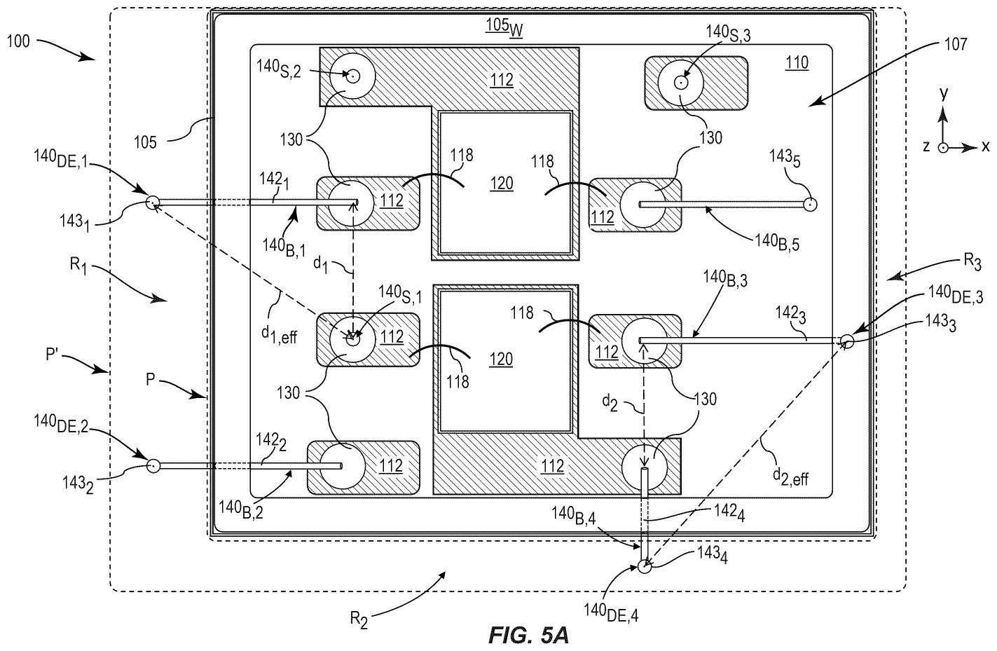

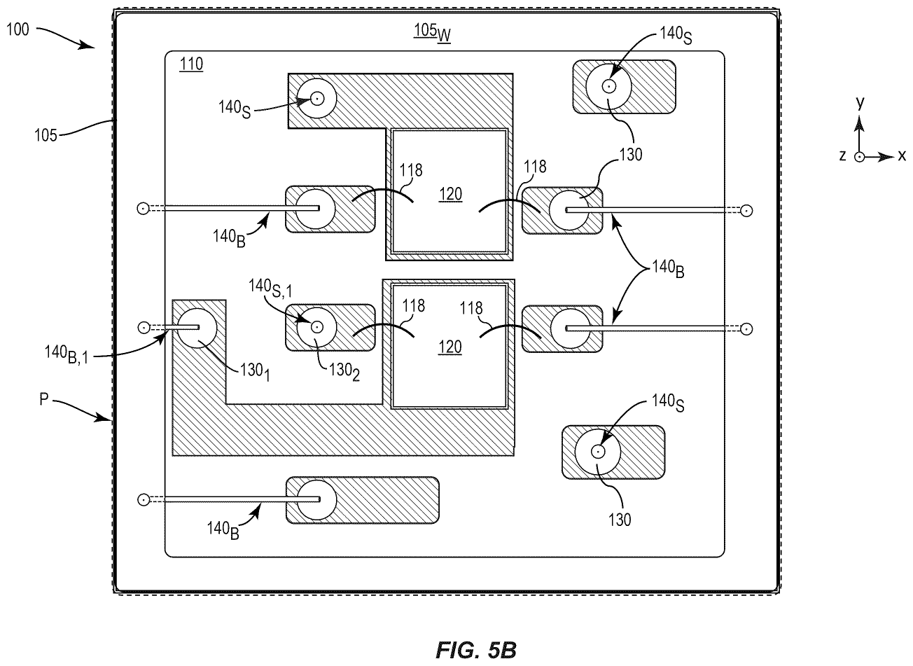

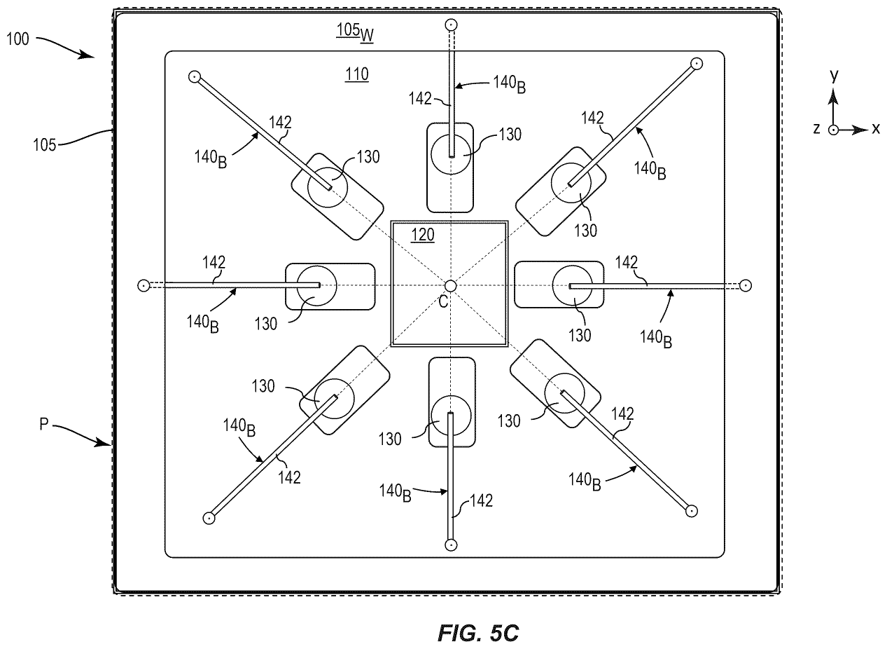

FIGS. 5A-5C illustrate top plan views of the electronic device 100, according to embodiments. The examples of FIGS. 5A-5C illustrate example arrangements and some of the specific advantages that may be provided by using bent pins 140_{B} in the electronic device 100. Note that the top 105_{T} of the enclosure 105 is omitted from FIGS. 5A-5C to better illustrate the features.

The electronic device 100 of FIG. 5A includes bent pins 140_{B,1}, 140_{B,2}, 140_{B,3}, 140_{B,4}, and 140_{B,5}, and straight pins 140_{S,1}, 140_{S,2}, and 140_{S,3}. Each of the bent pins 140_{B,1}, 140_{B,2}, 140_{B,3}, 140_{B,4}, and 140_{B,5}, and the straight pins 140_{S,1}, 140_{S,2}, and 140_{S,3} are inserted into a sleeve 130 that is attached to a metallization layer 112. The sleeves 130 are each attached to the metallization layer 112 (e.g., an island of the metallization layer 112). A respective island of the metallization layer 112 may be electrically coupled to one of the power semiconductor dies 120 directly (e.g., a power semiconductor die 120 is mounted on an island of the metallization layer) or may be electrically coupled to a power semiconductor die 120 by another means, e.g., a bond wire 118, such that a bent pin 140_{B} or a straight pin 140_{S} that is inserted into a sleeve 130 attached to the respective island of the metallization layer 112 is electrically coupled to the power semiconductor die 120.

Although not specifically illustrated, any of the bent pins 140_{B,1}, 140_{B,2}, 140_{B,3}, 140_{B,4}, and 140_{B,5}, and/or the straight pins 140_{S,1}, 140_{S,2}, and 140_{S,3} of FIG. 5A may be at least partly covered by an electrically insulative layer(s), e.g., as illustrated in FIGS. 4A-4C. Parts of any of the bent pins 140_{B,1}, 140_{B,2}, 140_{B,3}, 140_{B,4}, and 140_{B,5}, and/or the straight pins 140_{S,1}, 140_{S,2}, and 140_{S,3} may be uncovered, e.g. the distal ends 140_{DE} of the third segments 143.

FIG. 5A illustrates perimeters P and P′. The perimeter P is the outer perimeter of the electronic device 100 as illustrated and, in this example and the examples of FIGS. 5B and 5C, may also represent outer perimeters of the enclosure 105 and/or the substrate 110. The perimeter P′ represents an area that is required for a comparable electronic device with the same external layout of pins 140 (e.g., the position of the distal ends 140_{DE}) if no bent pins 140_{B} are used and all of the pins are straight pins 140_{S}. That is, using only straight pins 140_{S} for the layout illustrated would require the straight pins 140_{S} and the sleeves 130 to be placed on the substrate 110 at the same x-y positions as the third segments 143₁, 143₂, 143₃, 143₄, 143₅, of the bent pins 140_{B,1}, 140_{B,2}, 140_{B,3}, 140_{B,4}, 140_{B,5}, respectively, requiring the enclosure 105 and the substrate 110 to extend at least to the perimeter P′. It should be noted that the perimeter P′ accounts for the area that would be required on a substrate of a comparable electronic device to accommodate sleeves 130 for straight pins 140_{S} that are placed at the same locations as the third segments 143 of the bent pins 140_{B} in the electronic device 100 of FIG. 5A. The area marked by the regions R₁, R₂, and R₃ between the perimeters P and P′ thus represent an areal gain that may be provided by using the bent pins 140_{B} that are described herein. Specifically, the areal gains in the regions R₁ and R₂ are provided by extending the second segments 142₁, 142₂, and 142₄ of the bent pins 140_{B,1}, 140_{B,2}, and 140_{B,4}, respectively, through the wall 105_{W} of the enclosure 105 such that the respective third segments 143_{1,} 143₂, and 143₄ are positioned outside the perimeter P. The areal gain in the region R₃ is provided by extending the second segment 142₃ of the bent pin 140_{B,3} partly through the wall 105_{W} of the enclosure 105 such that the distal end 140_{DE,3} of the bent pin 140_{B,3} is aligned with the wall 105_{W} in the z direction. The areal gain that may be provided by using the bent pins 140_{B} may enable the electronic device 100 to use the same external layout of the pins 140 with a smaller substrate 110 and enclosure 105, potentially reducing the cost of manufacturing the electronic device 100 while maintaining compatibility of the electronic device 100 with existing applications.

The layout of FIG. 5A illustrates examples in which using the bent pins 140_{B} may provide the electronic device 100 with improved creepage and clearance. One such example is illustrated with the bent pin 140_{B,1} and the straight pin 140_{S,1} that are inserted into adjacent sleeves 130. The positions at which the bent pin 140_{B,1} and the straight pin 140_{S,1} are inserted into the sleeves 130 are separated by a spacing d₁. The clearance between an uncovered part of the bent pin 140_{B,1} (e.g., the distal end 140_{DE,1} of the third segment 143₁) and an uncovered part of the straight pin 140_{S,1} is determined by an effective spacing d_{1,eff} between the uncovered part of the straight pin 140_{S,1} and the uncovered part of the third segment 143₁ of the bent pin 140_{B,1} instead of the spacing d₁ between the positions at which the straight pin 140_{S,1} and the bent pin 140_{B,1} are inserted into the sleeves 130, as would be the case for two adjacent straight pins 140_{S}. That is, using bent pins 140_{B,1} may improve clearance and possibly creepage by providing a greater effective spacing between adjacent pins 140 without increasing the spacing between the adjacent pins 140 and sleeves 130 on the substrate 110. This may enable reduced spacing between adjacent pins 140 on the substrate 110 and thus the size of the substrate 110 to be reduced while still meeting creepage and clearance requirements, potentially providing a manufacturing cost reduction. Additionally, or alternatively, increasing the effective spacing between adjacent pins 140 by using one or more bent pins 140_{B} may enable high voltage pins 140 to be placed closer to low voltage pins 140. For example, the bent pin 140_{B,1} may be assigned a low voltage (e.g., a DC− potential or ground) and the straight pin 140_{S,1} may be assigned a high voltage (e.g., a DC+ potential). Alternatively, the bent pin 140_{B,1} may be assigned a high voltage and the straight pin 140_{S,1} may be assigned a low voltage.

Another example of using the bent pins 140_{B} to improve creepage and/or clearance of the electronic device 100 is illustrated with the bent pins 140_{B,3} and 140_{B,4} inserted into adjacent sleeves 130. The positions at which the bent pins 140_{B,3} and 140_{B,4} are inserted into the sleeves 130 are separated by a spacing d₂. In this example, the second segment 142₃ of the bent pin 140_{B,3} extends in the x direction and the second segment 142₄ of the bent pin 140_{B,4} extends in the y direction such that the uncovered distal ends of the bent pins 140_{B,3} and 140_{B,4} are separated by an effective spacing d_{2,eff}. In this example, the second segments 142₃ and 142₄ are substantially orthogonal to each other, although examples in which the second segments 142₃ and 142₄ are not orthogonal are contemplated. In this example, the bent pin 140_{B,3} may be assigned a low voltage and the bent pin 140_{B,4} may be assigned a high voltage. Alternatively, the bent pin 140_{B,3} may be assigned a high voltage and the bent pin 140_{B,4} may be assigned a low voltage.

The electronic device 100 of FIG. 5B includes a bent pin 140_{B,1} inserted into a first sleeve 130₁ disposed along the outer perimeter P of the substrate 110. A straight pin 140_{S,1} is inserted into a second sleeve 130₂ spaced inward from the outer perimeter P. In some examples, the bent pin 140_{B,1} may be assigned a low voltage and the straight pin 140_{S,1} may be assigned a high voltage. Alternatively, the bent pin 140_{B,1} may be assigned a high voltage and the straight pin 140_{S,1} may be assigned a low voltage.

The electronic device 100 of FIG. 5C includes a plurality of the bent pins 140_{B}. The second segments 142 of the plurality of the bent pins 140_{B} have a radial arrangement. Each of the second segments 142 of the radial arrangement are oriented along a direction that extends from a center point C that is within the outer perimeter P of the substrate 110.

Other arrangements of the features illustrated in FIGS. 5A-5C are contemplated.

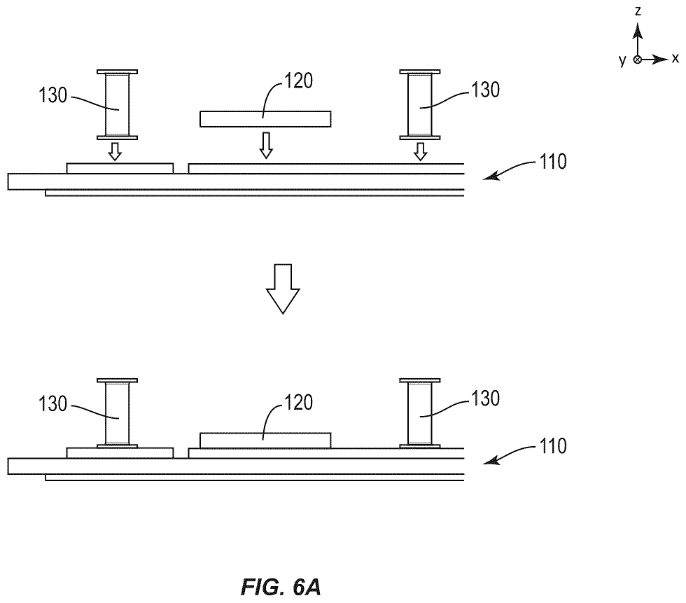

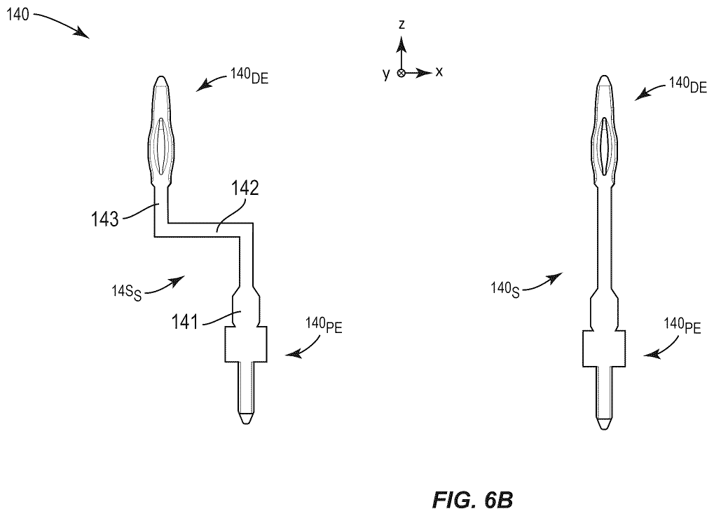

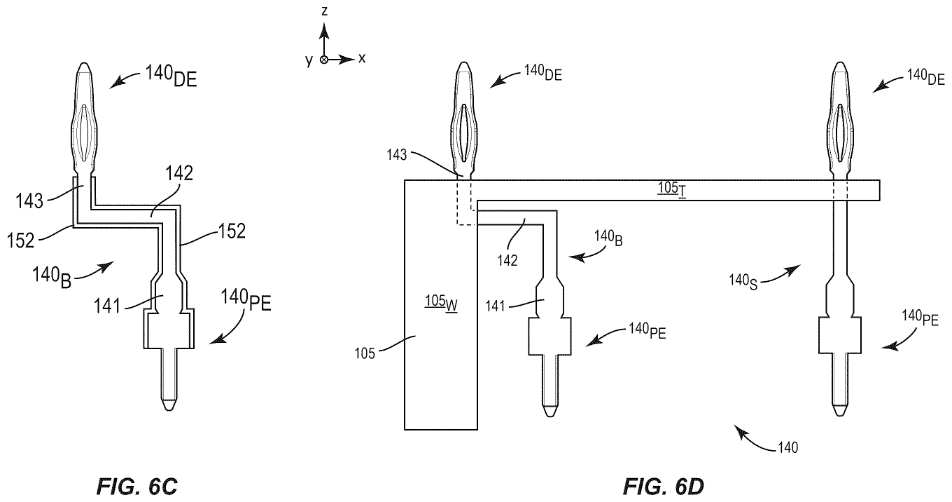

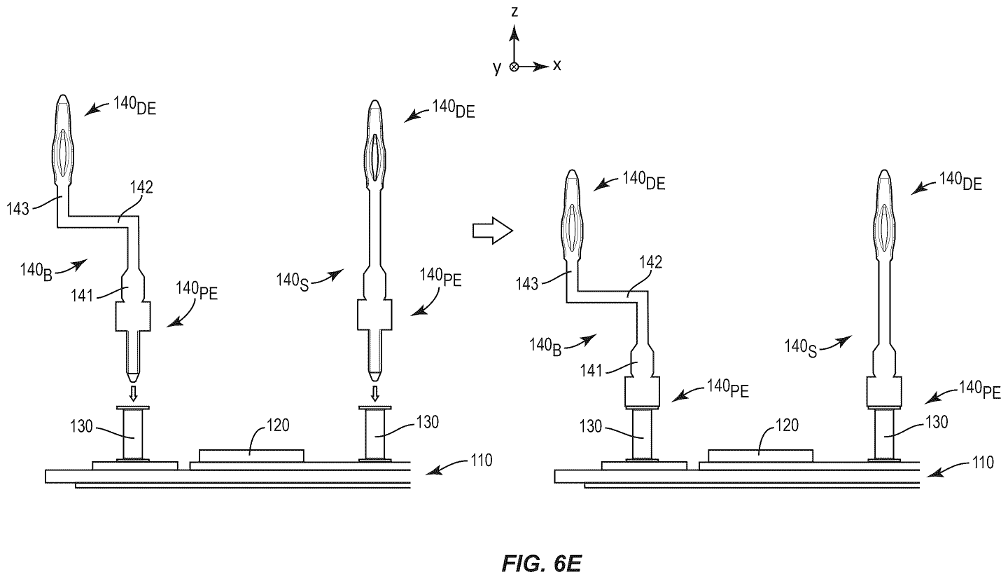

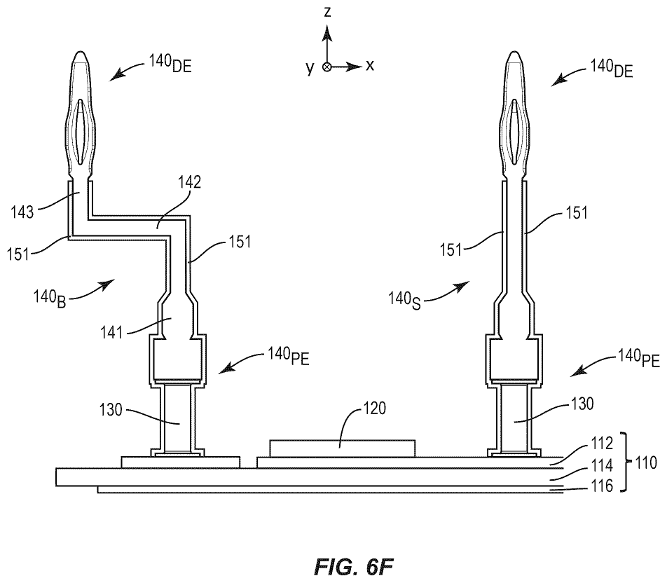

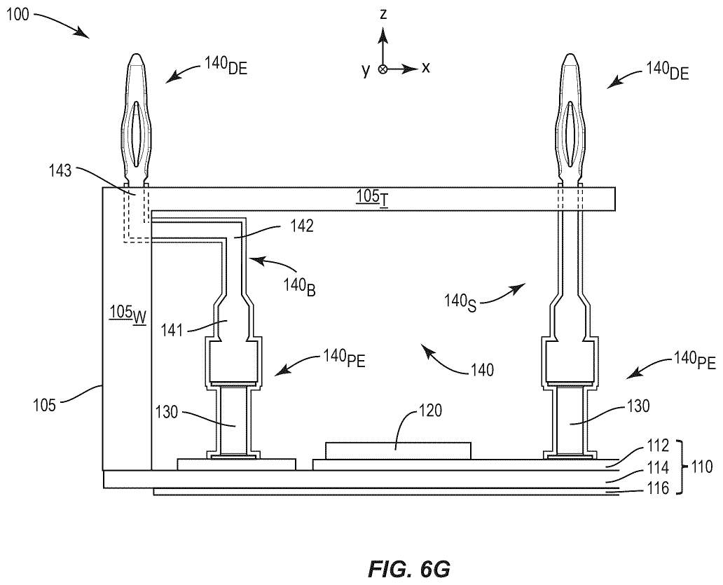

FIGS. 6A-6G illustrate partial side cross-sectional views of a method for producing the electronic device 100, according to embodiments.

FIG. 6A illustrates attaching a power semiconductor die 120 and a plurality of sleeves 130 to the substrate 110.

FIG. 6B illustrates providing a plurality of pins 140. In this example, one of the pins 140 is a bent pin 140_{B} and one of the pins is a straight pin 140_{S.}

FIG. 6C illustrates an alternative example of the bent pin 140_{B} provided in FIG. 6B. In this example, the bent pin 140_{B} is provided with an electrically insulative material 152 (e.g., the second electrically insulative material 152 of FIG. 4B) covering part of the first segment 141, the second segment 142, and part of the third segment 143. While subsequent examples of the method illustrate the bent pin 140_{B} as provided in FIG. 6B, any of the examples herein may alternatively include providing the bent pin 140_{B} of FIG. 6C.

FIG. 6D illustrates an alternative example of providing the plurality of pins 140. In this example, the bent pin 140_{B} and the straight pin 140_{S} are provided partly embedded in the electrically insulative enclosure 105. The enclosure 105 of FIG. 6D may, for example, be a molded frame 105 (e.g., as illustrated and described in FIGS. 3A and 3B), and the bent pin 140_{B} and the straight pin 140_{S} may be partly embedded in the molded frame 105 during formation of the molded frame 105, e.g., by inserting the bent pin 140_{B} and the straight pin 140_{S} into a mold and injecting a liquified mold compound around portions of the bent pin 140_{B} and the straight pin 140_{S}. While subsequent examples of the method illustrate the bent pin 140_{B} and the straight pin 140_{S} as provided in FIG. 6B, any of the examples herein may alternatively include providing the bent pin 140_{B} and the straight pin 140_{S} at least partly embedded in the enclosure 105 as illustrated in FIG. 6D.

FIG. 6E illustrates inserting the proximal end 140_{PE} of each of the bent pin 140_{B} and the straight pin 140_{S} into one of the plurality of sleeves 130. As noted previously, the proximal end 140_{PE} of one or both of the bent pin 140_{B} or the straight pin 140_{S} may be a press-fit end that is inserted into the sleeve 130.

FIG. 6F illustrates applying an electrically insulative material 151 (e.g., the first electrically insulative material 151 of FIG. 4B) to a part of the first segment 141, the second segment 142, and a part of the third segment 143 of the bent pin 140_{B}. In this example, the electrically insulative material 151 is also applied to part of the straight pin 140_{S} and to the sleeves 130. As noted previously, the bent pin 140_{B} may be provided with an electrically insulative material covering part of the bent pin 140_{B}, e.g., as illustrated and described for FIG. 6C. In these examples, applying the electrically insulative material 151 at this stage may be omitted, or may be limited to application to parts of the bent pin 140_{B}, the straight pin 140_{S}, and/or the sleeves 130.

FIG. 6G illustrates enclosing the power semiconductor die 120 in the electrically insulative enclosure 105 to produce the electronic device 100. The enclosure 105 is arranged such that the distal end 140_{DE} of each of the plurality of pins 140 is outside the enclosure 105 and provides an electrical interface for the electronic device 100. Enclosing the power semiconductor die 120 in the enclosure 105 may include attaching the wall 105_{W} to the substrate 110 and attaching the top 105_{T} (e.g., a lid) to the wall 105_{W}. In the example of the plurality of pins 140 and the molded frame 105 of FIG. 6D, wherein the bent pin 140_{B} and the straight pin 140_{S} are provided partly embedded in the molded frame 105, enclosing the power semiconductor die 120 in the enclosure 105 may include simultaneously inserting the proximal end 140_{PE} of each of the bent pin 140_{B} and the straight pin 140_{S} into one of the plurality of sleeves 130 (e.g., as illustrated and described in FIG. 6E), and enclosing the power semiconductor die 120 in the enclosure 105 (e.g., by attaching the enclosure, e.g., the wall 105_{W}, to the substrate 110).

Although the present disclosure is not so limited, the following numbered examples demonstrate one or more aspects of the disclosure.

Example 1. An electronic device, comprising: a substrate; one or more power semiconductor dies attached to the substrate; an electrically insulative enclosure that laterally encloses the one or more power semiconductor dies; a plurality of sleeves attached to the substrate; and a plurality of pins providing an electrical interface for the electronic device, each pin having a proximal end inserted into one of the plurality of sleeves and a distal end, wherein one or more of the pins has a bent profile and comprises: a first segment and a third segment that are oriented substantially perpendicular to the substrate and are offset from one another by a distance in a direction that is parallel to the substrate, the first segment comprising the proximal end of the pin and the third segment comprising the distal end of the pin; and a second segment interposed between and electrically coupling the first segment and the third segment, wherein at least a part of the first segment and at least a part of the second segment are covered by an electrically insulative material.

Example 2. The electronic device of example 1, wherein for at least one of the pins having the bent profile, the proximal end of the pin is a press-fit end comprising an anchoring part inserted into one of the plurality of sleeves.

Example 3. The electronic device of example 1 or 2, wherein for at least one of the pins having the bent profile, the distal end of the pin is a press-fit end comprising: a tip part configured to guide the press-fit end into an opening of a printed circuit board; and a deformable part adjoining the tip part and configured to deform upon insertion into the opening of the printed circuit board, wherein the tip part has a proximal region adjoining the deformable part and a distal region that is narrower than the proximal region.

Example 4. The electronic device of any of examples 1 through 3, wherein for at least one of the pins having the bent profile, the distal end of the pin is configured to be soldered to a printed circuit board.

Example 5. The electronic device of any of examples 1 through 4, further comprising: for at least one of the pins having the bent profile, a support separate from the enclosure and interposed between the substrate and the second segment and/or the third segment of the pin.

Example 6. The electronic device of any of examples 1 through 5, wherein the second segment extends between the first segment and the third segment in a direction that is substantially parallel to the substrate.

Example 7. The electronic device of any of examples 1 through 6, wherein for at least one of the pins having the bent profile, the third segment is positioned outside an outer perimeter of the substrate.

Example 8. The electronic device of any of examples 1 through 7, wherein a first pin inserted into a first sleeve is one of the pins having the bent profile, and wherein a second pin inserted into a second sleeve adjacent to the first sleeve has a straight profile.

Example 9. The electronic device of example 8, wherein the first pin is assigned a lower voltage than the second pin, or wherein the first pin is assigned a higher voltage than the second pin.

Example 10. The electronic device of any of examples 1 through 9, wherein a first pin inserted into a first sleeve disposed along an outer perimeter of the substrate is one of the pins having the bent profile, and wherein a second pin inserted into a second sleeve spaced inward from the outer perimeter has a straight profile.

Example 11. The electronic device of any of examples 1 through 10, wherein the second segment of a first pin having the bent profile extends in a first direction, and wherein the second segment of a second pin having the bent profile extends in a second direction that is different than the first direction.

Example 12. The electronic device of example 11, wherein the first direction and the second direction are substantially parallel to the substrate.

Example 13. The electronic device of any of examples 1 through 12, wherein the second segments of a plurality of the pins having the bent profile have a radial arrangement, each of the second segments of the radial arrangement oriented along a direction that extends from a center point that is within an outer perimeter of the substrate.

Example 14. The electronic device of any of examples 1 through 13, wherein the electrically insulative material is a coating.

Example 15. The electronic device of any of examples 1 through 13, wherein the electrically insulative material is a polyimide film.

Example 16. The electronic device of any of examples 1 through 13, wherein the electrically insulative material is a potting compound that at least partially fills an interior space delimited by the enclosure and the substrate.

Example 17. The electronic device of any of examples 1 through 16, wherein the one or more power semiconductor dies are SiC transistor dies.

Example 18. The electronic device of any of examples 1 through 17, wherein the enclosure is a molded frame that is attached to the substrate, and wherein for at least one of the pins having the bent profile, the pin is partly embedded in the molded frame.

Example 19. The electronic device of example 18, wherein for each pin having the bent profile and that is partly embedded in the molded frame, at least part of the second segment of the pin is embedded in the molded frame and the first segment is not embedded in the molded frame.

Example 20. A method for producing an electronic device, comprising: attaching one or more power semiconductor dies and a plurality of sleeves to a substrate; providing a plurality of pins, wherein one or more of the pins has a bent profile and comprises a first segment and a third segment that are oriented substantially perpendicular to the substrate and are offset from one another by a distance in a direction that is parallel to the substrate, the first segment comprising the proximal end of the pin and the third segment comprising the distal end of the pin; and a second segment interposed between and electrically coupling the first segment and the third segment; for each of the plurality of pins, inserting a proximal end of the pin into one of the plurality of sleeves; providing the one or more of the pins having a bent profile with at least a part of the first segment and at least a part of the second segment covered by an electrically insulative material, or, before or after inserting the proximal end of each of the one or more of the pins having a bent profile into one of the plurality of sleeves, applying an electrically insulative material to at least a part of the first segment and at least a part of the second segment of each of the one or more of the pins having a bent profile; and enclosing the one or more power semiconductor dies in an electrically insulative enclosure such that a distal end of each of the plurality of pins is outside the enclosure and provides an electrical interface for the electronic device.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An electronic device, comprising:
a substrate;
one or more power semiconductor dies attached to the substrate;
an electrically insulative enclosure that laterally encloses the one or more power semiconductor dies;
a plurality of sleeves attached to the substrate; and
a plurality of pins providing an electrical interface for the electronic device, each pin having a proximal end inserted into one of the plurality of sleeves and a distal end,
wherein one or more of the pins has a bent profile and comprises:
a first segment and a third segment that are oriented substantially perpendicular to the substrate and are offset from one another by a distance in a direction that is parallel to the substrate, the first segment comprising the proximal end of the pin and the third segment comprising the distal end of the pin; and
a second segment interposed between and electrically coupling the first segment and the third segment,
wherein at least a part of the first segment and at least a part of the second segment are covered by an electrically insulative material.

2. The electronic device of claim 1, wherein for at least one of the pins having the bent profile, the proximal end of the pin is a press-fit end comprising an anchoring part inserted into one of the plurality of sleeves.

3. The electronic device of claim 1, wherein for at least one of the pins having the bent profile, the distal end of the pin is a press-fit end comprising:
a tip part configured to guide the press-fit end into an opening of a printed circuit board; and
a deformable part adjoining the tip part and configured to deform upon insertion into the opening of the printed circuit board,
wherein the tip part has a proximal region adjoining the deformable part and a distal region that is narrower than the proximal region.

4. The electronic device of claim 1, wherein for at least one of the pins having the bent profile, the distal end of the pin is configured to be soldered to a printed circuit board.

5. The electronic device of claim 1, further comprising:
for at least one of the pins having the bent profile, a support separate from the enclosure and interposed between the substrate and the second segment and/or the third segment of the pin.

6. The electronic device of claim 1, wherein the second segment extends between the first segment and the third segment in a direction that is substantially parallel to the substrate.

7. The electronic device of claim 1, wherein for at least one of the pins having the bent profile, the third segment is positioned outside an outer perimeter of the substrate.

8. The electronic device of claim 1,
wherein a first pin inserted into a first sleeve is one of the pins having the bent profile, and
wherein a second pin inserted into a second sleeve adjacent to the first sleeve has a straight profile.

9. The electronic device of claim 8,
wherein the first pin is assigned a lower voltage than the second pin, or
wherein the first pin is assigned a higher voltage than the second pin.

10. The electronic device of claim 1,
wherein a first pin inserted into a first sleeve disposed along an outer perimeter of the substrate is one of the pins having the bent profile, and
wherein a second pin inserted into a second sleeve spaced inward from the outer perimeter has a straight profile.

11. The electronic device of claim 1,
wherein the second segment of a first pin having the bent profile extends in a first direction, and
wherein the second segment of a second pin having the bent profile extends in a second direction that is different than the first direction.

12. The electronic device of claim 11, wherein the first direction and the second direction are substantially parallel to the substrate.

13. The electronic device of claim 1,
wherein the second segments of a plurality of the pins having the bent profile have a radial arrangement, each of the second segments of the radial arrangement oriented along a direction that extends from a center point that is within an outer perimeter of the substrate.

14. The electronic device of claim 1, wherein the electrically insulative material is a coating.

15. The electronic device of claim 1, wherein the electrically insulative material is a polyimide film.

16. The electronic device of claim 1, wherein the electrically insulative material is a potting compound that at least partially fills an interior space delimited by the enclosure and the substrate.

17. The electronic device of claim 1, wherein the one or more power semiconductor dies are SiC transistor dies.

18. The electronic device of claim 1, wherein the enclosure is a molded frame that is attached to the substrate, and wherein for at least one of the pins having the bent profile, the pin is partly embedded in the molded frame.

19. The electronic device of claim 18, wherein for each pin having the bent profile and that is partly embedded in the molded frame, at least part of the second segment of the pin is embedded in the molded frame and the first segment is not embedded in the molded frame.

20. A method for producing an electronic device, comprising:
attaching one or more power semiconductor dies and a plurality of sleeves to a substrate;
providing a plurality of pins, wherein one or more of the pins has a bent profile and comprises a first segment and a third segment that are oriented substantially perpendicular to the substrate and are offset from one another by a distance in a direction that is parallel to the substrate, the first segment comprising the proximal end of the pin and the third segment comprising the distal end of the pin; and a second segment interposed between and electrically coupling the first segment and the third segment;
for each of the plurality of pins, inserting a proximal end of the pin into one of the plurality of sleeves;
providing the one or more of the pins having a bent profile with at least a part of the first segment and at least a part of the second segment covered by an electrically insulative material, or, before or after inserting the proximal end of each of the one or more of the pins having a bent profile into one of the plurality of sleeves, applying an electrically insulative material to at least a part of the first segment and at least a part of the second segment of each of the one or more of the pins having a bent profile; and
enclosing the one or more power semiconductor dies in an electrically insulative enclosure such that a distal end of each of the plurality of pins is outside the enclosure and provides an electrical interface for the electronic device.
